(19) United States
(12) Patent Application Publication
(10) Pub. No.: US 2011/0269269 A1
(43) Pub. Date: Nov. 3, 2011

(54) LASER ABLATION ALTERNATIVE TO LOW COST LEADFRAME PROCESS

(75) Inventors: Nghia T. TU, San Jose, CA (US); Will K. WONG, Belmont, CA (US); Jaime A. BAYAN, San Francisco, CA (US); Jesus ROCHA, Watsonville, CA (US); Anindya PODDAR, Sunnyvale, CA (US)

(73) Assignee: NATIONAL SEMICONDUCTOR CORPORATION, Santa Clara, CA (US)

(21) Appl. No.: 12/772,896

(22) Filed: May 3, 2010

(51) Int. Cl. H01L 21/82; H01L 21/56; H01L 21/00

(52) U.S. Cl. 438/113; 438/106; 438/127; 257/E21.502; 257/E21.602; 257/E21.001

(57) ABSTRACT

The present inventions relate generally to methods for packaging integrated circuits using thin foils that form electrical interconnects for the package. The foil includes a base layer (such as copper) with an optional plating layer (such as silver) suitable for improving adhesion of the bonding wires (or other connectors) to the foil. The base layer (or the plated surface if the foil is preplated) of the foil is patterned by laser ablation to define components (e.g. contacts) of a device area. The patterning is arranged to ablate entirely through selected portions of the plating layer and part, but not all, of the way through corresponding underlying portions of the base layer. In some embodiments, the metallic foil is partially etched after the laser ablation in order to deepen the trenches that define the patterning of the foil. Multiple dice may then be attached to die attach pad areas of the plated foil and electrically coupled to electrical contacts. Some embodiments contemplate encapsulating the dice, bonding wires, and portions of the plated foil with a plastic molding material. Portions of the metallic foil may then be removed by etching, laser ablation, or grinding. The resulting structure may then be singulated to form individual integrated circuit packages.

### FIELD OF THE INVENTION

The present invention relates generally to the packaging of integrated circuits (ICs). More particularly, the invention relates to packaging methods and arrangements involving thin foils.

### BACKGROUND OF THE INVENTION

There are a number of conventional processes for packaging integrated circuit (IC) devices. By way of example, many plastic IC packages utilize a metallic leadframe that has been stamped or etched from a metal sheet to provide electrical interconnects to external devices. The die may be electrically connected to the leadframe by means of bonding wires, solder bumps or other suitable electrical connections. In general, the die and portions of the leadframe are encapsulated with a molding material to protect the delicate electrical components on the active side of the die while leaving selected portions of the leadframe exposed to facilitate electrical connections to external devices, such as a printed circuit board (PCB).

At various times, package designs have been proposed that utilize a metal foil as the electrical interconnect structure in place of the leadframe. The metallic foil is typically significantly thinner than the metal sheets or panels used to form conventional leadframes. Consequently, foil-based IC packaging methods have the potential of reducing package thickness due in part to the reduced thickness of the metallic interconnect structure.

Some of the present inventors have previously described foil-based methods of packaging integrated circuits. By way of example, U.S. patent application Ser. No. 12/133,335, entitled “Foil Based Semiconductor Package,” filed Jun. 4, 2008; U.S. patent application Ser. No. 12/195,704, entitled “Thin Foil Semiconductor Package,” filed Aug. 21, 2008; U.S. patent application Ser. No. 12/571,202, entitled “Foil Based Semiconductor Package”, filed Sep. 30, 2009; and U.S. patent application Ser. No. 12/571,223, entitled “Foil Plating For Semiconductor Packaging”, filed Sep. 30, 2009 each describe improved foil based methods of packaging integrated circuits. Each of these prior applications is hereby incorporated by reference herein. In some of the described processes, a foil is bonded to a substantially rigid carrier during a portion of the fabrication process in order to prevent the foil from warping. Various methods may be used to pattern the foil in a manner suitable for use in integrated circuit packages. The patterned foils are then used in the packaging process.

Although a number of foil based packaging techniques exist, there are continuing efforts to develop even more efficient designs and methods for packaging integrated circuits.

### SUMMARY OF THE INVENTION

The claimed inventions relate generally to methods for packaging integrated circuits using thin foils that form electrical interconnects for the package. The foil includes a metallic base layer, such as copper. The base layer is preferably patterned by laser ablation to define components (e.g. contacts) of a device area. The patterning is arranged to ablate part, but not all, of the way through portions of the metallic base layer.

In some embodiments, the metallic base layer is preplated with a plating layer (such as silver) that is suitable for improving adhesion of the bonding wires (or other connectors) to the foil. When a plating layer is present, the laser is used to ablate entirely through selected portions of the plating layer and part, but not all, of the way through underlying portions of the metallic base layer to define components of a device area.

Preferably, dice are attached and electrically coupled to the foil after the laser ablation step patterns the foil. Thereafter the dice may be encapsulated using conventional encapsulation techniques. After the encapsulation, at least portions of the bottom surface of the foil are removed, thereby exposing the patterned components on the bottom surface of the encapsulated foils. In various embodiments, the removal may be performed by etching, grinding, laser ablation, or other suitable techniques. After removing portions of the bottom surface of the foil, the encapsulated foil may then be singulated to form multiple packaged integrated circuit devices.

In some embodiments, a protective material is applied to the base layer (or if there is a plating layer, to the metallic plating layer) before the laser irradiates the metallic foil. Preferably, the protective material is substantially transparent to the laser radiation. After the foil is patterned by laser ablation, the protective material may subsequently be removed from the plating layer. In some embodiments, the protective material may be a liquid, gel, or solid materials. Materials such as isopropyl alcohol work well in some applications.

In alternative embodiments, after patterning the foil with a laser, the ablated surface of the foil is etched to deepen the trenches that define the patterning of the foil. This etch step may be performed after ablating the foil but before removing the protective coating and attaching dice to the foil. The earlier laser ablation step preferably exposes portions of the metallic base layer, which allows the etch to remove underlying portions of the metallic base layer. In some embodiments, the metallic plating layer acts as an etch mask for etching portions of the base layer. In other embodiments without a metallic plating layer, the protective coating may be used as an etch mask.

In yet other embodiments, a metallic foil, which has a metallic base layer and a metallic plating layer, is adhered to a carrier before patterning the foil by laser ablation. In some applications, the carrier may be useful in providing structural support for the foil during processing. After laser ablation, multiple dice may be attached and electrically coupled to the foil. The dice and portions of the foil may then be encapsulated with a molding material, and the carrier may then be removed from the foil. After the carrier has been removed, portions of the bottom surface of the foil may be removed such that the patterned components are exposed on the bottom surface of the encapsulated foil. This removal may be accomplished by etching, grinding, laser ablation, or other appropriate techniques. The encapsulated foil may then be singulated to form multiple packaged integrated circuit devices.

### BRIEF DESCRIPTION OF THE DRAWINGS

The invention and the advantages thereof, may best be understood by reference to the following description taken in conjunction with the accompanying drawings in which:

FIG. 1 is a flow chart illustrating a foil based process for packaging integrated circuits.

FIG. 2 is a flow chart illustrating a process for packaging integrated circuit devices in accordance with one embodiment of the present invention.

FIGS. 3A-3J are diagrammatic side views of various stages of the integrated circuit packaging process of FIG. 2.

FIG. 3K is a diagrammatic side view of an integrated circuit package formed by the process illustrated in FIG. 2 after singulation according to one embodiment of the present invention.

FIG. 3L is a diagrammatic bottom view of the integrated circuit package shown in FIG. 3K.

FIG. 4 is an image showing top and cross-sectional side views, respectively, of a foil structure after a laser ablation step illustrated in FIGS. 3B and 3C.

FIG. 5A is an image showing a top view of a foil structure after wire bonding to patterned electrical contacts.

FIG. 5B is an enlarged image showing a top view of the foil structure of FIG. 5A.

FIG. 6A is a diagrammatic bottom view of the molded foil structure of FIG. 3G before sacrificial web removal according to one embodiment of the present invention.

FIG. 6B is a diagrammatic bottom view of the molded foil structure of FIG. 3H after sacrificial web removal according to one embodiment of the present invention.

FIG. 6C is an enlarged diagrammatic bottom view of a device area resulting from the etching process of FIG. 4B according to one embodiment of the present invention.

FIG. 6D is an image showing a top view of a foil structure which illustrates numerous patterned device areas.

FIG. 7A is a flow chart illustrating a process for packaging integrated circuit devices in accordance with a second embodiment of the present invention.

FIG. 7B is an image showing top and cross-sectional side views, respectively, of a foil structure after an optional shallow etch step subsequent to laser ablation.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present invention relates generally to the packaging of integrated circuits. More particularly, the invention relates to improved, low-cost methods for using a thin foil to form electrical interconnects in an integrated circuit package.

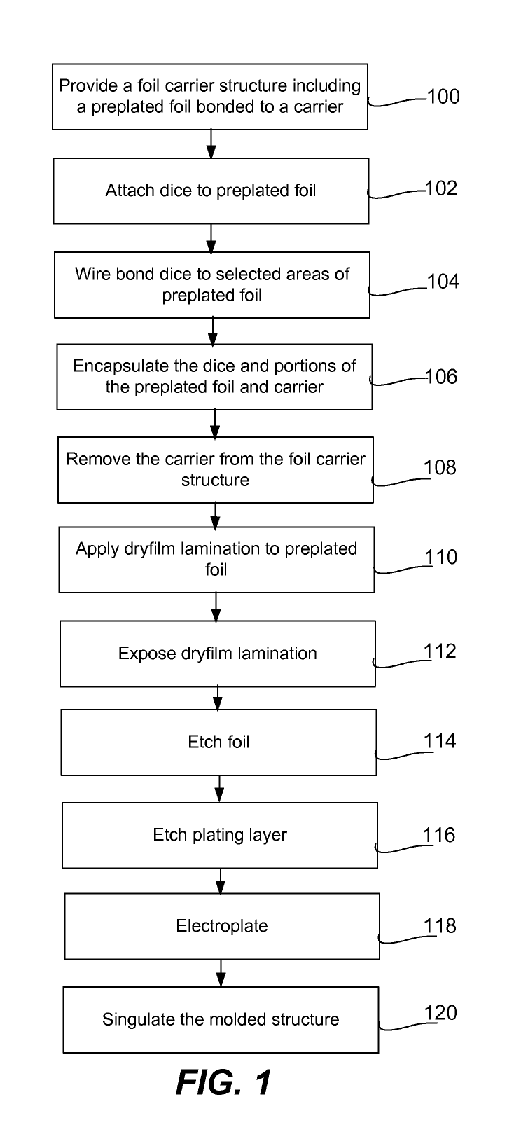

As mentioned in the background section, some of the inventors have previously proposed various foil based methods for packaging integrated circuits. One such technique is generally illustrated in FIG. 1. In this approach, a thin sheet of copper foil is secured to an aluminum carrier. The carrier provides structural support to the foil during various processing steps. The foil is intended for use in forming the package's contacts, and the exposed surface of the copper foil is preplated with a thin silver plating layer to facilitate subsequent wire bonding.

Referring now to FIG. 1, in step 102 a plurality of dice are attached to the preplated foil using conventional die attach techniques. The dice are then wire bonded to selected areas of the preplated foil in step 104 using conventional (typically gold) bonding wires. Portions of the foil carrier structure, dice, and bonding wires are then encapsulated with a plastic molding material in step 106 to form a molded foil carrier structure. After encapsulation step 106, the carrier is removed from the foil carrier structure (step 108) to form a molded foil structure. The carrier is no longer necessary after encapsulation step 106, because the plastic molding material provides sufficient structural support to facilitate handling during the remainder of the packaging process.

After the carrier has been removed, the foil is patterned using conventional photolithographic and etching techniques to form any desired metal structures, including the electrical contacts and optionally a die attach pad. As will be appreciated by to those familiar with the art, photo imaging based patterning techniques require several steps. Initially a photoresist is applied to the exposed surface of the foil by any suitable technique such as dryfilm lamination (Step 110). The photoresist is then photolithographically exposed to pattern the resist and unwanted portions of the resist are removed using conventional photoimaging techniques in step 112. The resulting structure leaves portions of the foil that are to be removed exposed, while portions of the foil to be retained are covered by the resist. After the resist has been patterned, exposed portions of the metallic foil are removed using a copper etch in step 114 to pattern the foil. Typically, different etchants are used to etch the copper foil and the silver plating. Therefore, a separate silver etching process 116 is used to remove the underlying portions of the silver plating layer after the copper foil etch has been completed. After the silver etch 116 has been completed, the remaining resist is stripped away to expose the retained portions of the foil and the patterning of the foil is completed. The resulting structures define the contacts associated with each package, as well as any die attach pads and bus bars that might be appropriate for a given panel.

After the foil patterning has been completed, solder is optionally electroplated onto the exposed electrical contacts in step 118, and the molded foil structure is singulated along predefined saw streets in step 120 to form individual integrated circuit packages. The described process can be used to successfully pattern thin metallic foils and to use the resulting patterned foil as electrical interconnects in integrated circuit packages.

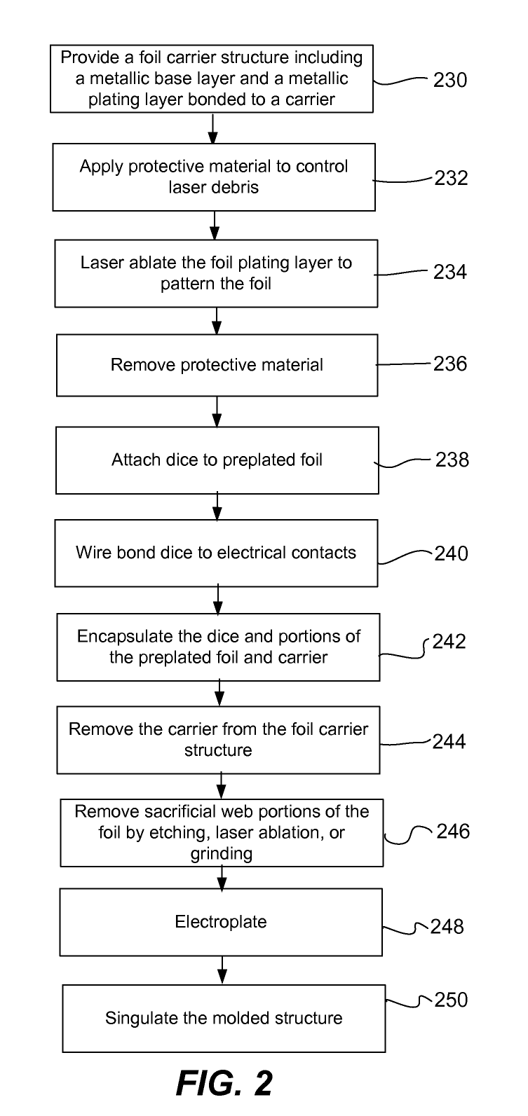

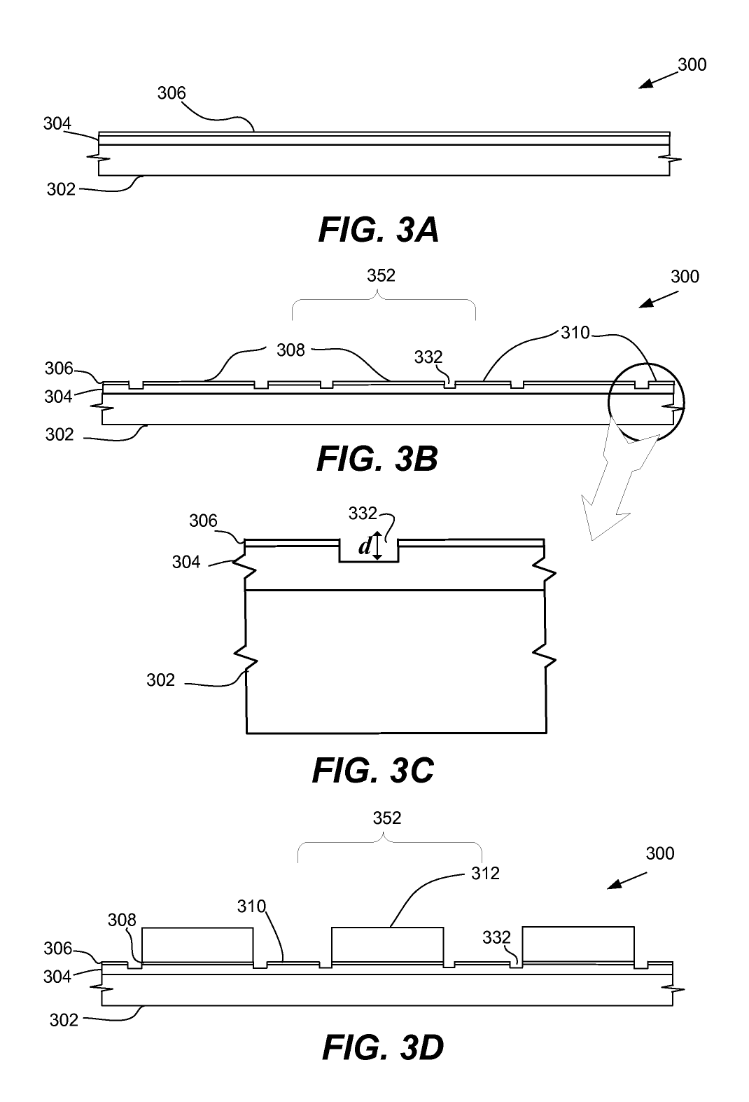

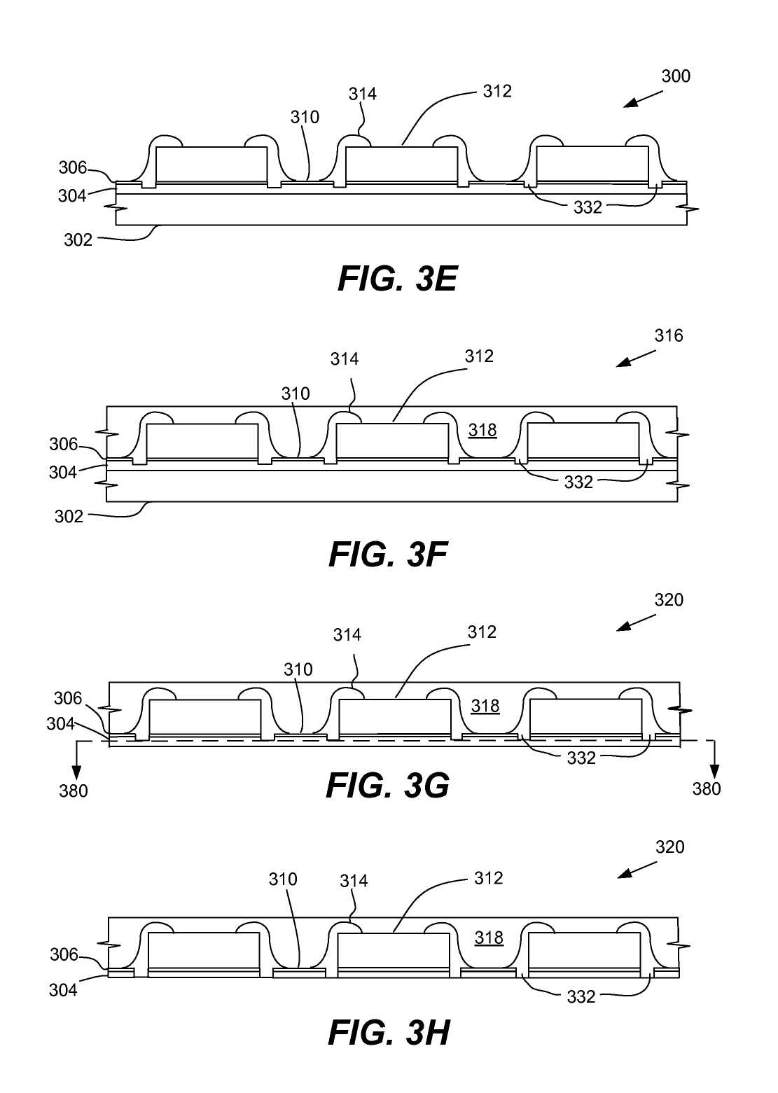

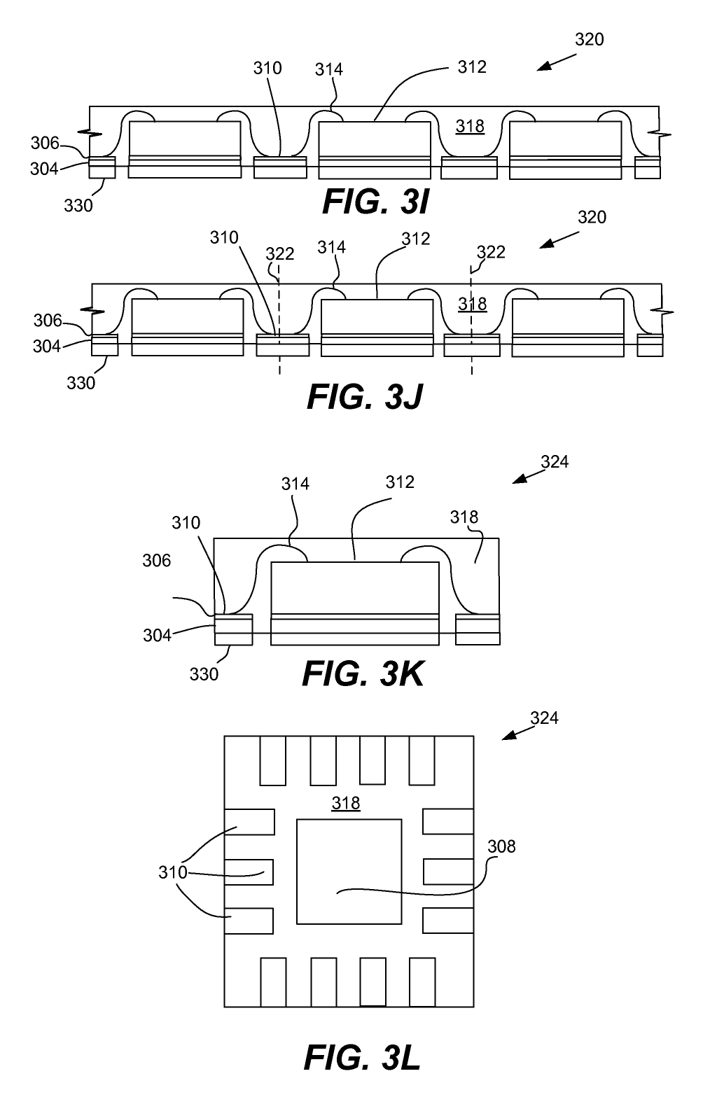

Although the method described with reference to FIG. 1 works well, the described photo imaging based etching approach requires several steps and may be relatively costly. Referring next to FIG. 2 in combination with FIGS. 3A-3L, an alternative foil based method of packaging integrated circuits will be described that eliminates the need for photolithographic based patterning. Like the approach described with reference to FIG. 1, this embodiment may begin with the use of a foil carrier structure 300 that includes a metallic foil mounted on a carrier 302. In the illustrated embodiment, the metallic foil includes a metallic base layer 304 that is pre-plated with a plating layer 306 that is suitable for improving adhesion of the bonding wires (or other connectors) to the foil (Step 230). In other embodiments, the composition of the foil may vary in accordance with the needs of any particular application. For example, in some embodiments the metallic foil may be composed of a single unplated metallic layer, e.g a copper foil.

In the embodiment shown in FIG. 3A, the metal foil includes a base layer 304 that is plated with a plating layer 306. The metallic foil 304 may be secured to the carrier using any suitable technique. By way of example, the foil may be ultrasonically bonded to an aluminum carrier as described in U.S. patent application Ser. No. 12/133,335 or Ser. No. 12/633,703, both of which are incorporated herein by reference. Of course, the foil may be secured to the carrier using other approaches as well. In still other embodiments where the packaging equipment is capable of handling the foil without a carrier, the carrier can be eliminated entirely.

The metallic foil base layer 304 may be composed of any metal suitable for use in electrical interconnects. By way of example, copper foil works well. Similarly, the plating layer 306 can be formed from any material that adequately improves the adhesion of bonding wires to the foil. By way of example silver works well. The thickness of the foil 304 can vary widely and can vary based on the needs of any particular application. For example, foil thicknesses in the range of 15-80 microns work well. The thickness of the metallic plating layer 306 may also vary widely based on the specific application. By way of example, silver plating layers in the range of approximately 2 microns to 5 microns work well. The carrier 302 should be sized suitably for handling by the packaging equipment that is used and thick enough to provide the necessary structural support for the foil 304.

In step 232 of FIG. 2, a substantially transparent, protective material is applied over the top surface of metallic plating layer 306. In embodiments without a plating layer, the protective material may be applied directly to the base layer 304, and the protective material may be substantially opaque to laser irradiation. The function of the protective material will be described in more detail below. The protective material may be composed of a variety of materials, including liquids, gels or solid materials. By way of example, optically transparent, water soluble materials such as liquid isopropyl alcohol work well for some applications.

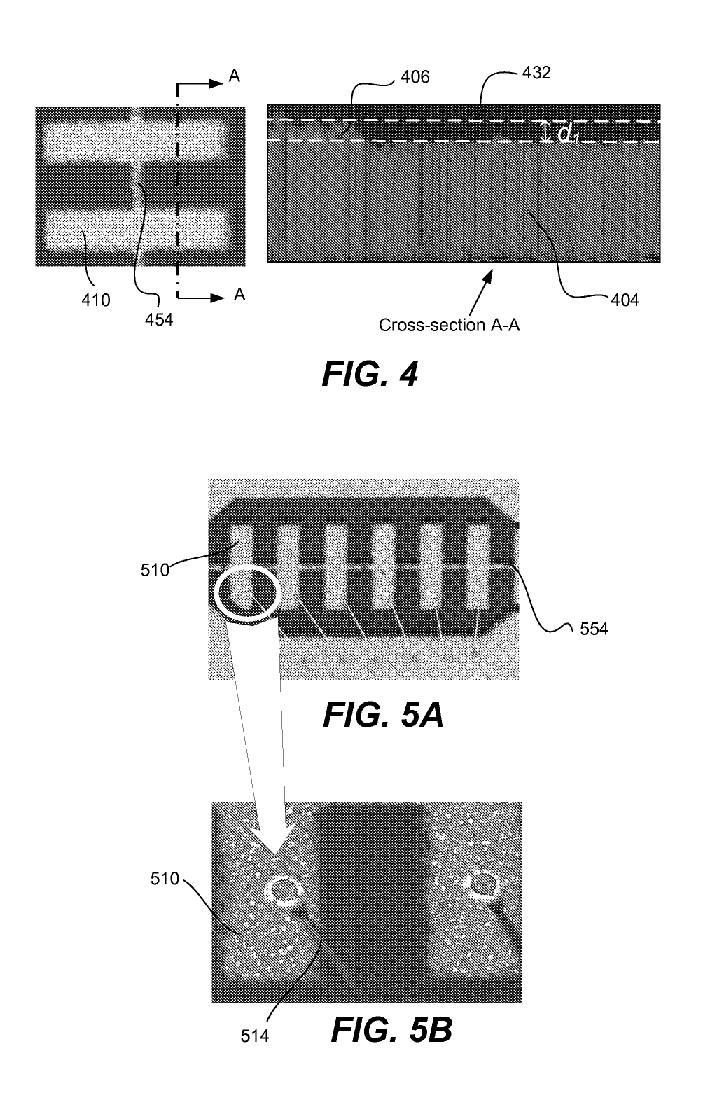

Turning to step 234, the foil is patterned by laser ablation. In general, one or more lasers are scanned across the surface of the foil in a pattern that defines multiple device areas 352 in the foil. In the illustrated embodiment, each device area 352 includes a die attach pad 308, a plurality of electrical contacts 310 and bus bars 454 (shown in FIG. 4), although more, different or fewer structures and components can be provided in each device area. Generally, the regions of the foil that are to be retained to form structures (e.g., contacts, die attach pads, bus bars, etc.) are not ablated, whereas all regions that are intended constitute voids in the finished product are ablated

The laser is scanned along the surface of the foil in a predefined pattern such that the energy of the impinging laser beam is sufficient to ablate portions of the metallic plating layer 306 and metallic base layer 304. The laser beam impinges on the top surface of the metallic plating later 306 and ablates the material, thereby creating a trench 332 that preferably completely removes the metallic plating layer 306 in the desired pattern. The laser ablation process also preferably removes part, but not all, of the underlying metallic base layer 304 during step 234, such that an intermediate portion of the foil 304 is exposed on the bottom of the trench 332. In embodiments without plating layer 306, the laser is scanned directly along the surface of base layer 304 to remove part, but not all, of the metallic base layer.

FIG. 3C is an enlarged illustration of the trench region 332 of FIG. 3B. The desired depth of the trench 332, d, depends on a variety of factors, including the respective thicknesses of the foil 304 and plating layer 306, and may therefore vary widely. Trench depths in the range of approximately 10 to 50 microns work well in many foil applications.

FIG. 4 is a micrograph of the laser ablated trench 432. The image on the left of FIG. 4 illustrates a plurality of electrical contacts 410 electrically connected by a bus bar 454. The bus bars 454 are optionally used in the later step 248 to electroplate solder onto the electrical contacts 410 for electrical connection to a substrate such as a PCB. Side cross-sectional view A-A is illustrated in the image on the right in FIG. 4. As shown in the image, laser ablation step 234 has removed material from the foil 404 and plating layers 406 to depth d₁ such that a portion of the foil base layer 404 is exposed at the bottom of the trench 432. Preferably, the laser completely removes the plating layer 406 and at least partially removes material from the foil 404.

A variety of different ablation lasers may be used to pattern the foil. One such laser may be obtained from DPSS Lasers, Inc. of Santa Clara, Calif. The laser is normally operated at power levels that are sufficient to ablate portions of the metallic plating layer 306 and foil layer 304. For example, lasers powered at approximately 3-5 Watts successfully ablate the foil 304 and plating layer 306. For faster ablation, higher power levels (as for example power levels in the 10-15 Watts range) may be appropriate. The appropriate power levels will vary with the nature of the laser used and the desired ablation characteristics. The laser may be operated at any wavelength that successfully ablates the foil 304 and plating layer 306. In some embodiments, the wavelength of the laser is preferably in the ultraviolet range of the spectrum. One specific laser that has successfully been used for the described ablation uses a wavelength of approximately 355 nanometers. While lasers of this type have been used in ablation applications in the past, such as for medical device applications, the current inventors are not aware of any previous uses of laser ablation to pattern thin metallic foils for use in integrated circuit packaging.

It has been observed that ablation of thin foils can generate debris. In some circumstances, the accumulation of debris may interfere with further ablation or subsequent processing. Consequently, it is sometimes desirable to capture the debris relatively close to its source. The primary purpose of the protective material applied in step 232 is to capture such debris. In this embodiment, the protective material is preferably substantially transparent to the wavelength(s) of light used by the laser. The laser can therefore pass through the protective material to facilitate ablation. Metallic debris generated by the ablation is trapped by the protective material so that the debris does not spread. By capturing debris created by the laser ablation, the protective material deposited in step 232 can effectively isolate and remove the unwanted debris when the material is rinsed from the foil carrier structure 300 in step 236. In step 236, water is preferably used to rinse the protective material from the foil carrier structure 300. While water is used to wash the protective material away in the described embodiment, other suitable solvents may be used as appropriate.

Turning to step 238 and FIG. 3D, dice 312 may then be mounted on corresponding die attach pad regions 308 of device areas 352 using conventional die attach techniques. In embodiments, such as the illustrated embodiment, wherein the region of the die attach pad has not been ablated, the adhesion surface of the die attach pad will be the plating layer 306. However, as will be appreciated by those familiar with the art, typical plating layers (e.g. silver) do not form particularly good die attach surfaces. Therefore, in alternative embodiments, it may be desirable to remove the metallic plating layer 306 from the die attach pad 308 before attaching the die 312 in order to further enhance the adherence of the die 312 to the die attach pad 308. This can be done as part of the initial laser ablation or using other suitable techniques. In embodiments without a plating layer the adhesion surface of the die attach pad will be base layer 304.

In step 240, illustrated in FIG. 3E, each die 312 is electrically coupled to corresponding electrical contacts 310 through conventional means such as wire bonding. It should be appreciated that the exposed surfaces of the contacts are formed from plating layer 306 to facilitate the wire bonding. As will be appreciated by those familiar with the art, gold is the material most commonly used in bonding wires and silver plating is typically used to enhance the bond between gold bonding wires and copper contacts. Therefore, plating layer 306 is preferably a silver plating layer. However, it should be appreciated that in alternative embodiments other suitable materials may be used as the plating layer and/or the bonding wires. One such alternative bonding technique utilizes Aluminum wedge bonding directly on a copper surface. FIGS. 5A-B are micrographs that show gold bonding wires 514 bonded to electrical contacts 510 coated with a silver plating layer. The electrical contacts 510 are optionally electrically connected with each other by bus bars 554. The experimental results depicted in FIGS. 5A-B indicate that the gold bonding wires 514 form a reliable bond with the silver-plated electrical contacts 510.

In step 242 and FIG. 3F, the dice 312, bonding wires 314, and portions of the metallic foil 304 and metallic plating layer 306 are then preferably encapsulated with a molding material 318 to form a molded foil carrier structure 316. The molding material 318 of FIG. 3F is preferably applied as a continuous strip such that the molding material 318 is distributed relatively evenly over the molded portions of the molded foil carrier structure 316. Note also that the molding material 318 preferably fills the trenches 332, which may also provide an improved locking mechanism to hold the molding material 318 in place. The molding material 318 applied in step 242 typically provides enough structural support for the thin metallic foil 304 such that the carrier 302 is no longer required. Consequently, in step 244 and FIG. 3G, the carrier 302 may be removed from the molded foil carrier structure 316 to form a molded foil structure 320.

After step 244, the electrical contacts 310 are still electrically coupled to each other and to the die attach pad 308 by thin portions of the foil 304 that remain below the trench regions 332 (sometimes referred to hereinafter as “sacrificial web portions”). To complete the patterning of the electrical contacts 310 and thereby electrically isolate them for use as contacts in an integrated circuit package, the sacrificial web portions of the foil are removed in step 246. In FIG. 3G, the sacrificial web portions removed in step 246 are illustrated by the foil material lying below dashed line 380. As illustrated in the embodiment of FIG. 3H and described in step 246, the backside of the metallic foil 304 is uniformly removed until the sacrificial web portion is completely removed and the portions of the molding material 318 lying inside trenches 332 are thereby exposed.

In one embodiment of step 246, the sacrificial web portions of the metallic foil 304 are uniformly removed by a conventional etch process in step 246. Example etch processes include plasma etching and wet etching, but any suitable etch process may be used that sufficiently removes the sacrificial web portions of the metallic foil 304. In an etching embodiment, the molding material 318 in the trenches 332 may therefore act as an etch stop.

In another embodiment of step 246, sacrificial web portions of the metallic foil 304 may be removed by laser ablation. For this embodiment, either the same laser used in step 234 or a different laser may be used to remove the sacrificial web portions of the metallic foil 304. Like the etching embodiment, the laser impinges on the backside of the molded foil structure 320 until the molding material 318 is exposed through the trenches 332.

Yet another embodiment of step 246 contemplates removing the sacrificial web portions of the metallic foil 304 by a grinding process. In the grinding embodiment, a grinding tool may be brought into contact with the backside of the molded foil structure 320 to remove the sacrificial web portions of the metallic foil 304 by applying sufficient mechanical energy to the foil 304. While these embodiments contemplate using etching, laser ablation, or grinding as material removal methods, other suitable processes may be used to remove the sacrificial web portions of the metallic foil 304.

The specific process chosen to remove the sacrificial web portions of foil 304 may depend, in part, upon the desired structure of the resulting contacts. For example, grinding will typically insure that bottom surfaces of the contacts 310 and the molding material 318 will be substantially coplanar. Etching and laser ablation can also be used to provide exposed contact surfaces that are substantially coplanar with the bottom surface of the molding material. If it is desirable to recess the contacts slightly relative to the bottom surface of the molding material, the etching parameters can be selected such that etching continues a desired amount past the molding material to thereby recess the contacts relative to exposed surfaces of the molding material. If it is desirable to have the contacts form posts that extend below the bottom surface of the molding material, laser ablation can be performed in a pattern that does not ablate the web in regions associated with the contacts and/or other structures that are intended to protrude below the molding material, while removing web portions appropriately to separate the contacts, etc.

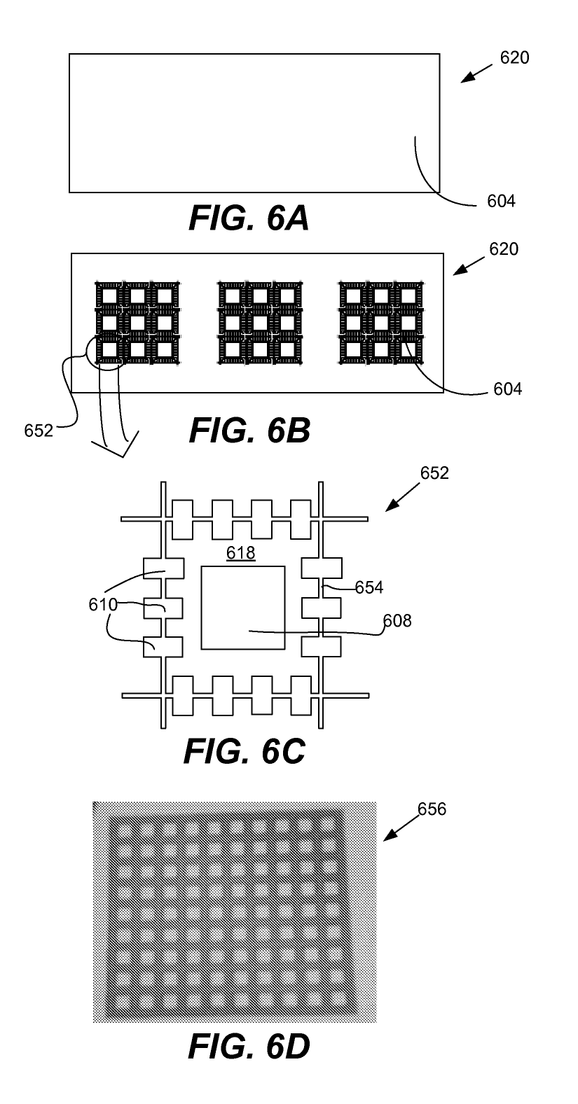

FIGS. 6A-C illustrate a bottom view of a typical molded foil structure 620 at various stages of sacrificial web removal step 246. FIG. 6A shows a bottom view of the molded foil structure 620 before the sacrificial web portions of the metallic foil 604 are removed. Note that before sacrificial web removal step 246, the backside of the molded foil structure 620 is a uniform foil surface. The molded foil structure 620 is then preferably etched, laser ablated, or grinded in step 246, which exposes the molding material 618 in the desired pattern to define multiple device areas 652 within the molded foil structure 620. For purposes of illustration, FIG. 6B depicts twenty-seven (27) total device areas 652, with one device area 652 illustrated in the enlarged diagram of FIG. 6C. The number and configuration of device areas 652 in other embodiments varies by application. For example, FIG. 6D illustrates a micrograph of a panel 656 containing numerous device areas produced by one embodiment of the present invention.

FIG. 6C illustrates one device area 652 of the embodiment presented in FIG. 6B. As described above, sacrificial web removal step 246 defines the electrical contacts 610 and die attach pad 608 by completely removing the portions of the foil 604 that underlie the trenches 632 until the molding material 618 is exposed.

Turning next to FIG. 3I and step 248, the exposed electrical contacts 310 may optionally be electroplated with a solder layer after foil removal step 246. Optional tie bars 654 like those shown in FIG. 6C may be used to electrically couple the electrical contacts 310 and the die attach pad 308 such that a single electroplating step may be used to plate the entire molded foil structure. Finally, in step 250 and FIG. 3J, the molded foil structure 320 is singulated along saw streets 322 to form multiple individual integrated circuit packages 324. Molded foil structure 320 may be singulated using a variety of techniques, including sawing and laser cutting. The singulation step 250 may also be used to sacrifice the optional tie bars 654 so that the electrical contacts 310 are ultimately electrically isolated from each other.

FIGS. 3K-L illustrate diagrammatic side and bottom views, respectively, of a singulated integrated circuit package 324. The bottom view in FIG. 3L shows the molding material 318 surrounding exposed contacts 310 and die attach pad 308. In embodiments with electroplated solder layer 330, the exposed electrical contacts 310 and die attach pad 308 would be further plated with a layer of solder 330. The electroplated solder layer 330 may then be used to electrically connect the final integrated circuit package 324 to a suitable substrate, such as a printed circuit board.

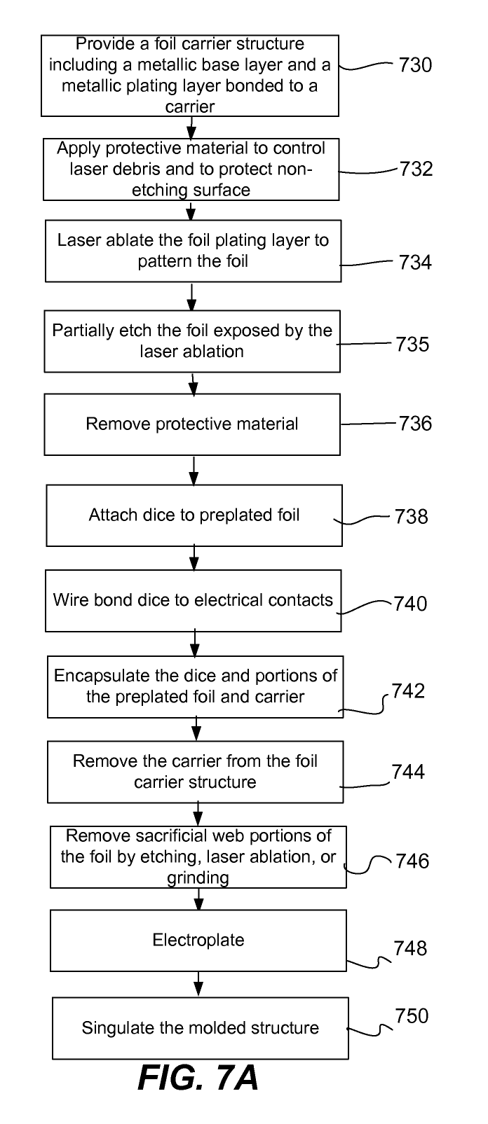

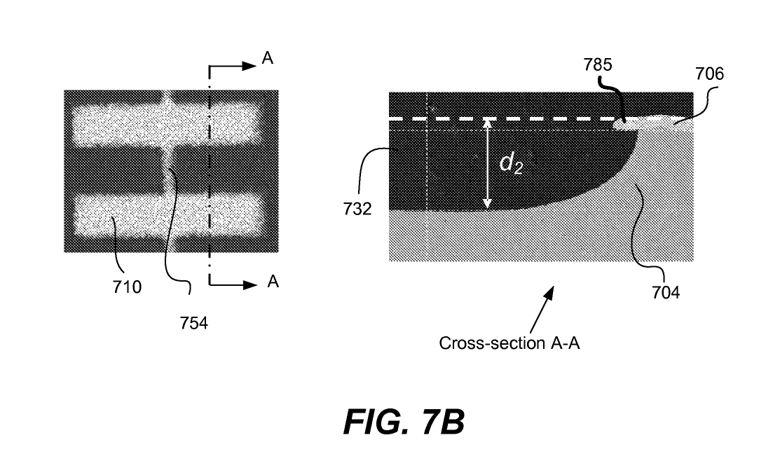

Referring next to FIG. 7A, yet another embodiment of the present invention will be described. This embodiment is similar in most respect to the process described with respect to FIG. 2, but adds a partial etch of the exposed surface of the foil after the laser ablation in a step 735. This partial etch step is sometimes referred to herein as a shallow etch. In other respects, the process may be quite similar to the process described above with reference to FIG. 2. In the embodiment illustrated in FIGS. 7A-B, the exposed intermediate surface of the plated foil 704 is partially etched before removing the protective material in step 736 and after laser ablation step 734. The etching is performed using an etchant that etches the base metal used in the foil (e.g. a copper etch) but not the plating material (e.g. silver) or the protective layer (when the protective layer is also used as an etch mask). Since the shallow etch does not etch the plating layer (such as silver), the plating layer may act as an etch mask to accurately pattern the underlying foil base layer 704. Thus, the shallow etch 735 may be used after laser ablation to create deeper trenches 732 without adversely affecting the exposed plating layers. Such a shallow etch has several potential advantages. Initially, laser ablation is currently a relatively slow process. When a shallow etch approach is used, the initial laser ablation does not need to ablate as much material to form the trenches. Rather, the ablation only needs to proceed long enough to fully ablate through the silver plating layer. The subsequent shallow etch 735 can then be used to attain the desired trench depth.

In another shallow etch embodiment, the foil may include only an unplated base layer 704, which does not require the use of separate plating layer 706. In this case, the protective material applied in step 732 is applied directly to the base layer 704 (which may be copper). The shallow etching 735 is performed using an etchant that etches the base metal 704 used in the foil (e.g. a copper etch) but not the protective layer, such that the protective material may act as an etch mask to protect non-etch surfaces. As noted above, this is particularly useful in embodiments that do not utilize a plating layer, although the protective layer can also be used as an etch mask in the patterning of plated foils if desired. It should be appreciated that in embodiments that contemplate using the protective layer as an etch mask, it will typically be desirable to use an opaque solid or gel material as the protective coating. When the protective coating is opaque to the laser irradiation, laser ablation step 734 can be used to ablate the protective coating and thereby pattern the foil without using a plating layer 706. With this arrangement, the laser ablation is arranged to first ablate the protective layer. If the foil does not include a plating layer, the ablation step does not need to significantly ablate the foil since the patterning of the protective layer provides sufficient patterning to facilitate etching. In this case, the ablation only needs to proceed long enough to fully ablate through the protective material and thereby expose the underlying foil base layer 704.

Shallow etch step 735 may be accomplished by any suitable etching technique, including wet etching, plasma etching, etc. The desired depth of the trenches 732 formed by the shallow etching step 735 may be varied to meet the needs of any specific application and will depend in large part on the thickness of the foil. By way of example, total trench depths (i.e., the combined depth of the laser ablation and shallow etch) in the range of approximately 10-50 microns work well for most applications.

FIG. 7B illustrates a micrograph of a trench 732 created by shallow etch step 735 when a silver plating layer is utilized. As shown in the image and the embodiment of FIG. 7A, silver plating layer 706 has been completely removed in the trench region, and a copper foil layer 704 has been partially etched to a depth d₂. In embodiments with a metallic plating layer, the shallow etch also has the benefit of forming an interlock feature between the foil and the molding material. Specifically, the etchant tends to undercut edge portions 785 of the plating layer as best seen in FIG. 7B. This undercut 785 will fill with molding material during a subsequent molding operation. The undercut 785 thus forms an interlock between the foil and the molding material.

The methods of FIGS. 2 and 7A are improvements over the method of FIG. 1 in a few respects. For example, the photolithographic based patterning and etching (e.g. steps 110, 112, and 116 of FIG. 1) are not required in the embodiments of FIGS. 2 and 7A. By using laser ablation to directly pattern the foil 304, there is no need to apply and expose a photoresist to create a pattern suitable for etching. Also, because the laser ablation completely removes the metallic plating layer 306 during the patterning step 234, there is no need to separately etch the plating layer from the backside. Removing these steps can result in substantial cost savings associated with the packaging process. In addition, in some embodiments the wire bonding operation may be simplified as well. In the embodiment of FIG. 1, the wire bonding is done before the device areas are defined. This can be difficult for some wire bonding machines because there may not be good reference fiducials for use in aligning the wire bonding capillary. In contrast, the laser patterning of the foil prior to the wire bonding results in the formations of discrete contacts which are easily identifiable by conventional wire bonding machines.

Although only a few embodiments of the invention have been described in detail, it should be appreciated that the invention may be implemented in many other forms without departing from the spirit or scope of the invention. For example, while the integrated circuit packages illustrated in FIGS. 3K-L resemble Quad Flat No Lead (QFN) packaging styles, it should be appreciated that the methods of the present invention may also be suitable for use in a wide range of packaging styles configurations. Therefore, the present embodiments should be considered as illustrative and not restrictive and the invention is not limited to the details given herein, but may be modified within the scope and equivalents of the appended claims.

What is claimed is:

1. A method for packaging integrated circuits comprising:
providing a metallic foil;
irradiating the metallic foil with a laser to ablate part, but not all, of portions of the foil to pattern the metallic foil in a manner suitable for use in integrated circuit packaging, wherein the patterned metallic foil includes a multiplicity of distinct device areas, each device area including a plurality of electrical contacts.

2. A method for packaging integrated circuits comprising:
providing a metallic foil having a metallic base layer and a metallic plating layer plated on the base layer; and
irradiating the metallic foil with a laser to ablate portions of the metallic plating layer and part, but not all, of corresponding underlying portions of the metallic base layer to pattern the metallic foil in a manner suitable for use in integrated circuit packaging, wherein the patterned metallic foil includes a multiplicity of distinct device areas, each device area including a plurality of electrical contacts.

3. A method as recited in claim 2, further comprising:
after irradiating the metallic foil, attaching a multiplicity of dice to a corresponding multiplicity of device areas; and
electrically coupling each die of the multiplicity of dice to associated electrical contacts in an associated device area.

4. A method as recited in claim 3, further comprising encapsulating the multiplicity of dice and at least a portion of the metallic foil with a molding material.

5. A method as recited in claim 4, further comprising after encapsulation, removing portions of the metallic foil from a bottom surface of the metallic foil until the molding material is exposed, using a method selected from the group consisting of etching, grinding, and laser ablation, wherein the bottom surface of the metallic foil is substantially opposite the plated surface of the metallic foil.

6. A method as recited in claim 2, wherein irradiation of the metallic foil removes portions of the metallic foil to a depth ranging from approximately 10 microns to 50 microns.

7. A method as recited in claim 2, wherein the metallic base layer is a copper layer, and wherein the metallic plating layer is a silver plating layer.

8. A method as recited in claim 2, wherein the thickness of the metallic foil ranges from approximately 15 to 80 microns.

9. A method as recited in claim 2, wherein the thickness of the metallic plating layer ranges from approximately 2 to 5 microns.

10. A method as recited in claim 2, further comprising:
before irradiating the metallic foil, applying a protective material over the metallic plating layer, wherein the protective material is substantially transparent to the laser radiation.

11. A method as recited in claim 10, further comprising:
after irradiating the metallic foil, removing the protective material.

12. A method for packaging integrated circuits comprising:
providing a metallic foil;
applying a protective material to the metallic foil;
irradiating the protective material with a laser to ablate portions of the protective material to expose underlying portions of the foil and thereby pattern the metallic foil in a manner suitable for use in integrated circuit packaging, wherein the patterned metallic foil includes a multiplicity of distinct device areas, each device area including a plurality of electrical contacts; and
after irradiating the protective material, etching the exposed underlying portions of the foil, wherein the etching forms trenches that extend partially through the foil.

13. A method for packaging integrated circuits comprising:
providing a metallic foil having a metallic base layer and a metallic plating layer plated on the base layer;
irradiating the metallic foil with a laser to completely remove portions of the metallic plating layer to expose portions of the underlying base layer to thereby pattern the metallic foil in a manner suitable for use in integrated circuit packaging, wherein the patterned metallic foil includes a multiplicity of distinct device areas, each device area including a plurality of electrical contacts; and
after irradiating the metallic foil, etching the exposed portions of the base layer, wherein the etching forms trenches in the base layer that extend partially through the foil.

14. A method as recited in claim 13, further comprising:
before irradiating the metallic foil, applying a protective material to the metallic foil, wherein the protective material is substantially transparent to the laser radiation.

15. A method as recited in claim 14, further comprising:
after etching the exposed portions of the base layer, removing the protective material;
after removing the protective material, attaching a multiplicity of dice to a corresponding multiplicity of device areas;
electrically coupling each die of the multiplicity of dice to associated electrical contacts in an associated device area.

16. A method as recited in claim 15, further comprising:
encapsulating the multiplicity of dice and at least a portion of the metallic foil with a molding material.

17. A method as recited in claim 16, further comprising:
after encapsulation, removing portions of the metallic foil from a bottom surface of the metallic foil until the molding material is exposed, using a method selected from the group consisting of etching, grinding, and laser ablation, wherein the bottom surface of the metallic foil is substantially opposite the plated surface of the metallic foil.

18. A method as recited in claim 13, wherein irradiation of the metallic foil removes portions of the metallic foil to a depth ranging up to approximately 10 to 50 microns.

19. A method as recited in claim 13, wherein the metallic base layer is a copper layer, and wherein the metallic plating layer is a silver plating layer.

20. A method as recited in claim 2, further comprising:
providing a foil carrier structure, wherein the metallic foil is adhered to a carrier;
before irradiating the metallic foil, applying a protective material to the metallic foil;
after irradiating the metallic foil, removing the protective material;
after removing the protective material, attaching a multiplicity of dice to a corresponding multiplicity of device areas;
electrically coupling each die of the multiplicity of dice to associated electrical contacts in an associated device area;
encapsulating the multiplicity of dice and at least a portion of the metallic foil with a molding material to form a molded foil carrier structure;
removing the carrier from the molded foil carrier structure to form a molded foil structure;
after the carrier has been removed, removing portions of the metallic foil from a bottom surface of the metallic foil until the molding material is exposed, using a method selected from the group consisting of etching, grinding, and laser ablation, wherein the bottom surface of the metallic foil is substantially opposite the plated surface of the metallic foil;
after removing portions of the metallic foil, singulating the molded foil structure to provide a multiplicity of packaged integrated circuit devices.

21. A method as recited in claim 20, further comprising:
etching the ablated portions of the metallic base layer,
wherein the etching of the metallic base layer is performed before removing the protective material and after irradiating the metallic foil.
